(19) United States
(12) Patent Application Publication
(10) Pub. No.: US 2016/0315243 A1
(43) Pub. Date: Oct. 27, 2016

(54) CHARGED PARTICLE BEAM PROCESSING OF THERMOELECTRIC MATERIALS

(71) Applicants: Junqiao Wu, Richmond, CA (US); Joonki Suh, Albany, CA (US); Kin M. Yu, Lafayette, CA (US); Wladyslaw Walukiewicz, Kensington, CA (US)

(72) Inventors: Junqiao Wu, Richmond, CA (US); Joonki Suh, Albany, CA (US); Kin M. Yu, Lafayette, CA (US); Wladyslaw Walukiewicz, Kensington, CA (US)

(73) Assignee: The Regents of the University of California, Oakland, CA (US)

(21) Appl. No.: 15/060,849

(22) Filed: Mar. 4, 2016

Related U.S. Application Data
(60) Provisional application No. 62/151,276, filed on Apr. 22, 2015.

(51) Int. Cl. H01L 35/34; H01L 35/16

(52) U.S. Cl. CPC H01L 35/34; H01L 35/16

(57) ABSTRACT

This disclosure provides systems, methods, and apparatus related to thermoelectric materials. In one aspect, a thermoelectric material is provided. The thermoelectric material is then irradiated with charged particles to generated native defects in the thermoelectric material. The charged particles have energies of 100 keV or greater. The irradiation of the thermoelectric material may improve its thermoelectric properties.

### RELATED APPLICATIONS

This application claims priority to U.S. Provisional Patent Application Ser. No. 62/151,276, filed Apr. 22, 2015, which is herein incorporated by reference.

### STATEMENT OF GOVERNMENT SUPPORT

This invention was made with government support under Contract No. DE-AC02-05CH11231 awarded by the U.S. Department of Energy and under Grant No. DMR-1055938 (NSF CAREER Award) awarded by the National Science Foundation. The government has certain rights in this invention.

### BACKGROUND

Thermoelectrics have been heavily investigated over the past several decades for applications ranging from waste-heat recovery to solid-state refrigeration. The figure-of-merit (ZT) of thermoelectric materials is given by α²σT/κ, in which α is the Seebeck coefficient (thermopower), σ is the electrical conductivity, T is absolute temperature, and κ is the thermal conductivity. Since α and σ are anti-correlated through the free carrier concentration (n), recent successes to enhance ZT have mostly relied on reduction of lattice thermal conductivity (κₗ) without significantly affecting the power factor (α²σ). This approach has achieved ZT of PbTe-SrTe compounds exceeding 2 at temperatures above 900 K by effectively scattering and reducing all-length-scale mean free paths of acoustic phonons.

The best single-phase materials (i.e., excluding superlattices) available today for near-room-temperature thermoelectrics are Bi₂Te₃-based bulk alloys, and their best ZT is still around 1, e.g., n-type Bi₂Te_{2.7}Se_{0.3} with ZTₘₐₓ ˜0.9 and p-type Bi_{0.5}Sb_{1.5}Te₃ with ZTₘₐₓ ˜1.2. The approach of phonon engineering has limited potential for these materials as their thermal conductivity is already low and does not have much room for further reduction. A breakthrough in materials engineering that would improve ZT beyond what is limited by the trade-off between α and σ, preferably with a single methodology, is needed. Various experimental (e.g., energy filtering in Bi₂Te₃/Bi₂Se₃ superlattices) and theoretical (e.g., hybridization by topological surface states) approaches have been attempted or proposed to increase ZT by improving only α or σ, but not both. The trade-off between α and σ originates fundamentally from the fact that a high α prefers a large asymmetry in electron population above and below the Fermi level, thus a rapid variation in the material density of states; this is opposite to the direction of increasing σ and n, which occurs typically as the Fermi level is displaced deep into the band where the density of states is relatively constant.

### SUMMARY

As described herein, the thermoelectric figure of merit of materials may be enhanced by irradiating them with charged particles. In this process, native point defects generated by the irradiation break the usual antagonistic coupling among the three key thermoelectric parameters: electrical conductivity, thermal conductivity, and thermopower.

The efficiency of heat-to-electricity energy conversion, as gauged by the thermoelectric figure-of-merit, is inherently limited by antagonistic coupling among electrical conductivity, thermal conductivity, and thermopower. Enhancements in the electrical conductivity and thermopower are normally mutually exclusive. As described herein, simultaneous increases in electrical conductivity (up to 200%) and thermopower (up to 70%) by introducing native defects in Bi₂Te₃ films, leading to a high power factor of 3.4×10⁻³ W m⁻¹ K⁻² are possible. The maximum enhancement of power factor occurs when the native defects act beneficially as electron donors as well as energy filters to mobile electrons. The native defects also act as effective phonon scatterers.

Details of one or more embodiments of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a flow diagram illustrating a process for improving the thermoelectric properties of a thermoelectric material.

FIG. 2 shows an example of a flow diagram illustrating a process for improving the thermoelectric properties of a thermoelectric material.

FIGS. 3A-3D show the characterization of pristine Bi₂Te₃ films.

FIGS. 4A-4C show the electrical transport of native defect-engineered Bi₂Te₃ films.

FIGS. 5A and 5B show the bilayer Hall-effect modeling of Bi₂Te₃ films.

FIGS. 6A-6C show the enhancement of the Seebeck coefficient and power factor by the native defects.

FIG. 7 shows cross-plane (c-axis) thermal conductivity (κ_{⊥}) versus irradiation dose for Bi₂Te₃ films.

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

In the following description, numerous specific details are set forth in order to provide a thorough understanding of the present invention. Particular example embodiments of the present invention may be implemented without some or all of these specific details. In other instances, well known process operations have not been described in detail in order not to unnecessarily obscure the present invention.

Various techniques and mechanisms of the present invention will sometimes be described in singular form for clarity. However, it should be noted that some embodiments include multiple iterations of a technique or multiple instantiations of a mechanism unless noted otherwise.

A new way to enhance thermoelectric properties of thermoelectric materials, such as Bi₂Te₃, for example, by utilizing native defects (NDs) is described herein. A new, atomic-scale mechanism to break the trade-off between α and σ, simultaneously improving both for enhanced ZT, is presented. Such a unique combination of electrical and thermoelectric benefits originates from the multi-functionality of native point defects in thermoelectric materials acting as electron donors and electron energy filters. The results presented in the EXAMPLE (below) establish the importance of understanding and controlling point defects in thermoelectric materials as a venue to much improve their device performance.

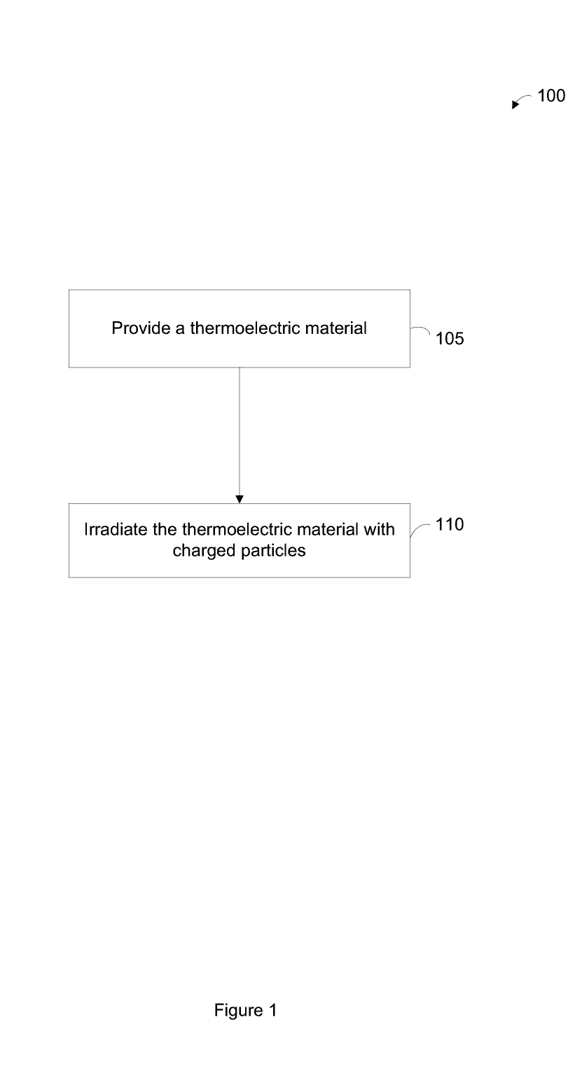

FIG. 1 shows an example of a flow diagram illustrating a process for improving the thermoelectric properties of a thermoelectric material. Starting at block 105 of the method 100, a thermoelectric material is provided. In some embodiments, the thermoelectric material comprises an antimony-based thermoelectric material, a bismuth-based thermoelectric material, or a lead-based thermoelectric materials. For example, in some embodiments, the thermoelectric material comprises a material selected from a group consisting of an antimony telluride-based material, an antimony selenide-based material, a bismuth telluride-based material, a bismuth selenide-based material, a lead telluride-based material, a lead selenide-based material, a tin telluride-based material, and a tin selenide-based material. In some embodiments, the thermoelectric material is Bi₂Te₃.

In some embodiments, the thermoelectric material is about 0.5 microns to 300 microns thick. In some embodiments, the thermoelectric material is about 5 microns to 15 microns thick, or about 10 microns thick.

At block 110, the thermoelectric material is irradiated with charged particles to generate native defects in the thermoelectric material. In some embodiments, the charged particles have energies of about 100 keV or greater. In some embodiments, the charged particles are selected from a group consisting of protons, alpha particles (i.e., helium ions), nitrogen ions, and neon ions. In some embodiments, when the charged particles comprise protons, the charged particles have energies of about 1 MeV to 100 MeV. In some embodiments, when the charged particles comprise alpha particles, the charged particles have energies of about 1 MeV to 100 MeV. In some embodiments, when the charged particles comprise nitrogen ions, the charged particles have energies of about 100 keV to 2 MeV. In some embodiments, when the charged particles comprise neon ions, the charged particles have energies of about 100 keV to 2 MeV.

The charged particles may be provided by any type of device capable of accelerating charged particles. For example, the charged particles may be provided by a cyclotron, a high voltage accelerator, or a focused ion beam apparatus.

In some embodiments, the thermoelectric material is in a vacuum environment when it is irradiated with the charged particles. For example, the vacuum of the vacuum environment may be about 10⁻³ torr or lower. In some embodiments, the thermoelectric material is in air (e.g., not in a vacuum environment) when it is irradiated with the charged particles. When the thermoelectric material is in air, the thermoelectric material should be close to the charged particles exit point from the charged particle source so that the charged particles loose little energy.

A purpose of the irradiation is to generate native defects in the thermoelectric material. Native defects, which may also be referred to intrinsic defects, include vacancies, interstitial atoms, and anti-site defects. An anti-site defect is a defect where an atom is in an improper lattice site in crystalline material containing two or more elements. Extrinsic defects are foreign atoms in a crystal lattice (e.g., a boron dopant in silicon). Generally, the charged particles used for the irradiation do not react with thermoelectric material so that no extrinsic defects are generated. Also, if charged particles that are too massive are used for the irradiation, the penetration depth of the charged particles in the thermoelectric material will be shallow (e.g., the charged particles will not penetrate thermoelectric material except near the surface) and defects will be generated only at the surface of the thermoelectric material.

In some embodiments, the charged particles have enough energy to pass through the thermoelectric material. When the charged particles have enough energy to pass through the thermoelectric material, no charged particles are deposited in the thermoelectric material. For example, in some embodiments, the charged particles having enough energy to pass through the thermoelectric material can aid in preventing accumulation of potentially reactive species (e.g., H or N) in the thermoelectric material that can affect the properties of the thermoelectric material.

In some embodiments, the charged particles do not have enough energy to pass through the thermoelectric material. In some embodiments, the charged particles not having enough energy to pass through the thermoelectric material (e.g., when the charged particles are noble gas ions or nonreactive gas ions (e.g., Ne or He)) will not affect the properties of the thermoelectric material. In some embodiments, noble gas ions or nonreactive gas ions, when deposited in the thermoelectric material, form clusters of atoms that do not chemically react with the thermoelectric material.

The damage to the crystal structure of the thermoelectric material imparted by the charged particles may be characterized by the displacement damage dose (DDD, or D_{d}) of the thermoelectric material. More massive charged particles will damage a material more. DDD describes the total displacement damage energy deposited per unit mass of material, and can be obtained by multiplying the ion fluence Φ by the respective non-ionizing energy loss (NIEL) in a material; DDD=NIEL×Φ. Lighter charged particles have a lower NIEL, so they require a larger fluence to achieve the same DDD compared to heavier charged particles. DDD also depends on the composition of the material being irradiated with the charged particles.

In some embodiments, the thermoelectric material is irradiated with alpha particles to a dose of about 1×10¹⁴ per cm² to 3×10¹⁴ per cm², corresponding to a DDD of about 10¹² MeV/g to 10¹⁴ MeV/g, depending on the thermoelectric material. In some embodiments, the thermoelectric material is irradiated with protons, neon ions, or nitrogen ions to a dose of about 1×10¹⁴ per cm² to 3×10¹⁴ per cm², corresponding to a DDD of about 10¹² MeV/g to 10¹⁴ MeV/g, depending on the thermoelectric material.

When Bi₂Te₃ is the thermoelectric material, in some embodiments, the free carrier concentration or the electron density in the thermoelectric material after irradiation with the charged particles is about 1×10¹⁹ to 5×10¹⁹ per cm³. The free carrier concentration in a thermoelectric material after irradiation with charged particles is material dependent. In some embodiments, after a thermoelectric material is irradiated with charged particles, the native defect density in the thermoelectric material is on the same order as the free carrier concentration (e.g., electron density) in the thermoelectric material.

In some embodiments, the defect density (i.e., a density of native defects) in the thermoelectric material after the irradiation is about 10¹⁸ to 10²⁰ defects per cm³. In some embodiments, irradiating the thermoelectric material with charged particles increases the Seebeck coefficient (thermopower) and the electrical conductivity of the thermoelectric material. In some embodiments. irradiating the thermoelectric material with charged particles increases the Seebeck coefficient of the thermoelectric material to greater than about 200 microvolts per Kelvin.

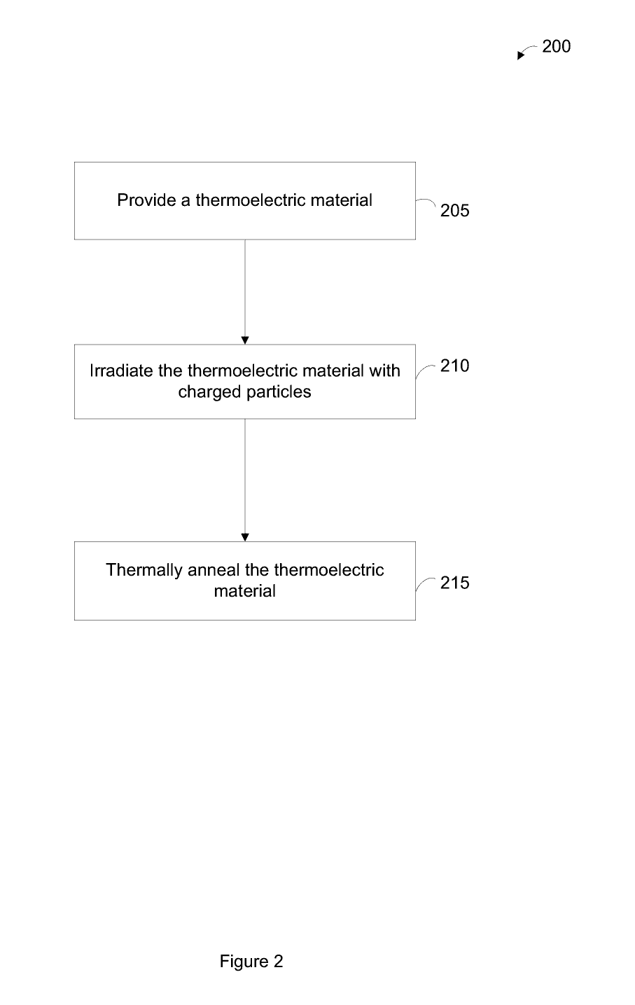

FIG. 2 shows an example of a flow diagram illustrating a process for improving the thermoelectric properties of a thermoelectric material. Blocks 205 and 210 in the method 200 are the same operations as blocks 105 and 110, respectively, in the method 100 shown in FIG. 1. At block 215 of the method 200, after the thermoelectric material is irradiated with charged particles, the thermoelectric material is thermally annealed. In some embodiments, the thermoelectric material is thermally annealed at about 100° C. to 600° C. for a time period of about 30 seconds to 30 minutes. In some embodiments, the thermal annealing is performed with the thermoelectric material in a vacuum environment. In some embodiments, the thermal annealing is performed with the thermoelectric material in a nitrogen atmosphere.

### EXAMPLE

The following examples are intended to be examples of the embodiments disclosed herein, and are not intended to be limiting.

Bi₂Te₃ thin-films with a wide range of thicknesses (11 nm to 740 nm) were grown by molecular beam epitaxy (MBE) on semi-insulating GaAs (001) substrates. Layer-by-layer growth was monitored in situ by reflection high-energy electron diffraction with typical growth rates of 0.5 to 2 quintuple layers per minute (QL/min). Later, the compositions and thicknesses of the films were confirmed by Rutherford backscattering spectrometry before further experiments.

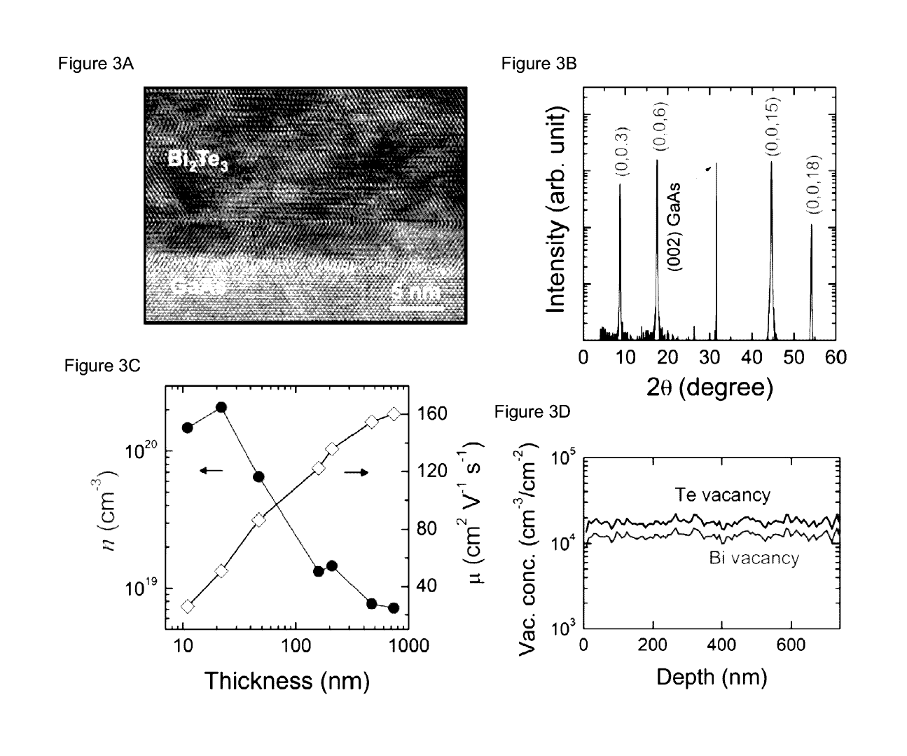

FIGS. 3A-3D show the characterization of pristine B₂Te₃ films. The microstructure of the Bi₂Te₃ films was investigated using cross-section high-resolution transmission electron microscopy (HRTEM). In FIG. 3A, the cross-section image of a Bi₂Te₃ film grown on semi-insulating GaAs (001) substrate shows clean interfaces without amorphous phases, and shows highly parallel QLs. The crystallinity of the MBE films was further evaluated by X-ray diffraction (XRD) using the Cu K_{α1} radiation line (FIG. 3B). The XRD pattern clearly shows strong reflections from {003}-type lattice planes. This is a strong indication of the highly c-axis directional growth of the MBE films. The QL thickness was calculated from the XRD data, giving d_{QL}=1.014±0.005 nm for Bi₂Te₃ that is consistent with the value of 1.016 nm for bulk Bi₂Te₃.

Hall-effect measurements were performed at room temperature for all pristine Bi₂Te₃ films with thicknesses ranging from 11 nm to 740 nm (FIG. 3C). Electron concentration decreases and carrier mobility increases monotonically with film thickness, and tends to saturate in thicker films, akin to those observed in Bi₂Se₃ MBE thin films.

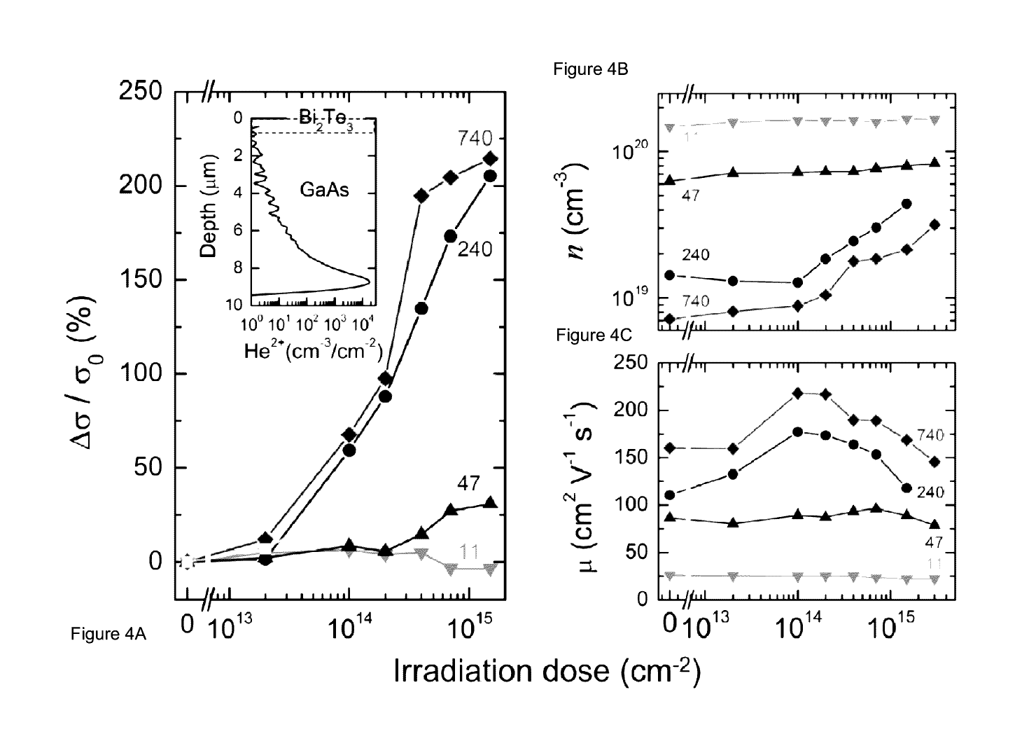

In order to generate NDs, the samples were irradiated with 3 MeV alpha particles (He²⁺) with doses ranging from 2×10¹³ cm⁻² to 3×10¹⁵ cm⁻². The projected range of these particles exceeds 8 μm in Bi₂Te₃, as calculated by Monte Carlo simulation using the Stopping and Range of Ions in Matter (SRIM) program (FIG. 4A, inset). Therefore, the He²⁺ ions completely pass through the entire film thickness, leaving behind NDs that are uniformly distributed in both lateral and depth directions.

FIG. 3D shows the concentration of vacancies that was calculated using SRIM for 740-nm thick Bi₂Te₃ film under 3 MeV alpha particles irradiation. As predicted by SRIM, the primary NDs induced by irradiation are Bi (V_{Bi}) and Te (V_{Te}) vacancies and corresponding interstitials with average densities of 1.2×10⁴ (for Bi) and 1.8×10⁴ cm⁻³/ion-cm⁻²(for Te), respectively, that scale linearly with the irradiation dose (FIG. 3D). As indicated by the units (cm⁻³/cm⁻²), the real vacancy concentration is given by this value multiplied with the irradiation dose (in units cm⁻²), implying a linear dependence between them. Note that within the doses used, the materials are gently damaged with only point defects generated; no extended defects, surface sputtering, non-stoichiometry or amorphization is observed. Also note that the substrate (semi-insulating GaAs) does not contribute to the electrical conductivity measured from the film. It is theoretically expected and experimentally confirmed that the substrate remains electrically extremely insulating after the irradiation, with a sheet resistance orders of magnitude higher than that of the film.

FIGS. 4A-4C show the electrical transport of ND-engineered Bi₂Te₃ thin films. FIG. 4A shows the electrical conductivity variation upon irradiation of films with different thicknesses (in nm), as noted. The inset shows the depth distribution of the irradiation He²⁺ ions in the Bi₂Te₃ film and GaAs substrate determined by SRIM simulation,

After the irradiation, σ of the Bi₂Te₃ increases for films with thickness between 47 and 740 nm, and this trend is more significant for thicker films (FIG. 4A). Considering the multiple conduction channels (e.g., surface and bulk) in Bi₂Te₃, this effect suggests that bulk transport, which is affected by the NDs, plays an important role in the electrical conductance in this thickness range. In contrast, very thin films are insensitive to irradiation, because surface conduction dominates and remains robust to irradiation.

FIG. 4B shows the electron concentration and FIG. 4C shows the electron mobility of representative Bi₂Te₃ films as a function of irradiation dose, determined by Hall-effect measurement at room temperature. Hall effect measurements reveal that the enhanced σ is a combined effect of a monotonic increase in the bulk electron density (n) and a non-monotonic change of electron mobility (μ) (FIGS. 4B and 4C). The increase in n indicates that the irradiation predominantly introduces donor-like NDs, which are also considered as the primary reason for the unintentional n-type behavior of as-prepared Bi₂Te₃. This observation is consistent with a recent report of n-type doping in Bi₂Te₃ using electron irradiation.

As shown in FIG. 4C, the mobility of thick films increases (by up to 50%) upon irradiation until an intermediate dose (˜2×10¹⁴ cm⁻²), then steadily decreases. For conventional semiconductors, it is believed that NDs produced by irradiation are charged Coulomb scattering centers, lowering the carrier relaxation time and thus the carrier mobility. Recent theoretical and experimental studies have shown that in addition to the bulk transport, Bi₂Te₃ exhibits significant surface or grain boundary transport, which is attributed to the topological insulator state or to a surface accumulation layer. It is proposed that the irradiation-induced NDs cause the unusual mobility behavior of FIG. 4C by modifying the relative contribution of conduction electrons between the bulk and the surface (including grain boundaries and specimen surface). Simplifying the system into two electrically conduction channels, surface and bulk, the dependence of carrier concentration and mobility on irradiation dose was modeled.

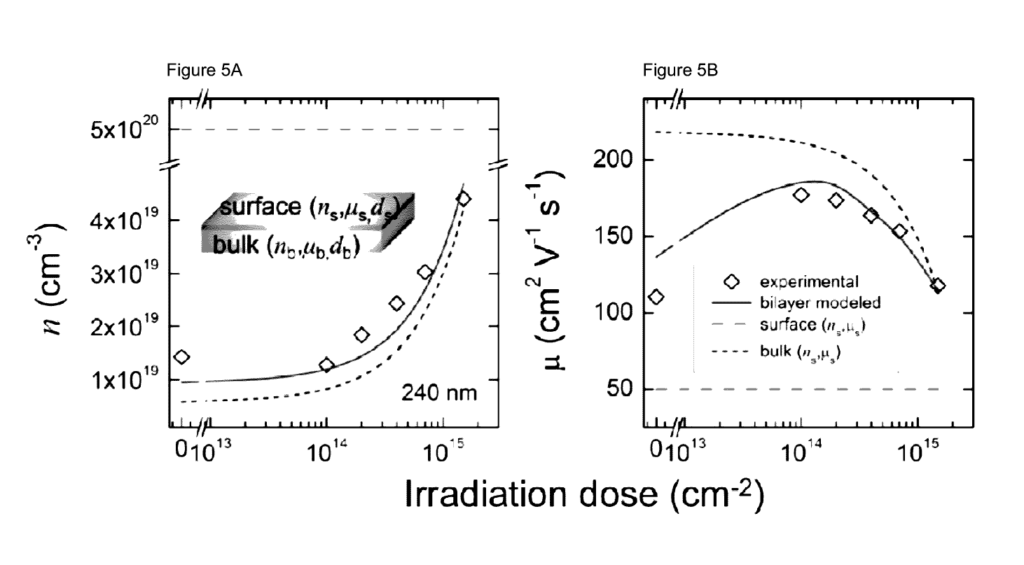

FIGS. 5A and 5B show the bilayer Hall-effect modeling of Bi₂Te₃ films. FIG. 5A shows a comparison of electron concentration and FIG. 5B shows a comparison of electron mobility between experimental data with bilayer modeled data for a 240 nm film. The inset in FIG. 5A shows schematics of the two conduction channels of surface and bulk. Surface properties are assumed to be constant for all the films within the ranges of thickness and irradiation dose.

As illustrated in the inset of FIG. 5A, parallel electron transport was considered in the surface and bulk layers. With the relative contribution from each layer, effective (modeled) electron concentration (n*) and mobility (μ*) were determined using

$$\begin{matrix}{n}^{*} = \frac{{[ {n}_{s} {μ}_{s} ( {d}_{s} / d ) + {n}_{b} {μ}_{b} ( {d}_{b} / d ) ]}^{2}}{{n}_{s} {μ}_{s}^{2} ( {d}_{s} / d ) + {n}_{b} {μ}_{b}^{2} ( {d}_{b} / d )} , & ( 1 ) \\ {μ}^{*} = \frac{{n}_{s} {μ}_{s}^{2} ( {d}_{s} / d ) + {n}_{b} {μ}_{b}^{2} ( {d}_{b} / d )}{{n}_{s} {μ}_{s} ( {d}_{s} / d ) + {n}_{b} {μ}_{b} ( {d}_{b} / d )} , & ( 2 )\end{matrix}$$

where nₛ(n_{b}) and μₛ(μ_{b}) are the electron concentration and mobility of surface (bulk) layer, respectively, and dₛ(d_{b}) is the thickness of surface bulk) layer, and the total thickness, d, is given by d=dₛ+d_{b}. The surface properties (nₛ and μₛ) are inferred from Hall-effect data of very thin films (11 nm to 22 nm) where surface contribution is dominant. Note that in this model nₛ and μₛ are assumed to be not strongly affected by irradiation, i.e., the irradiation generates more free electrons only in the bulk (increasing net n_{b}), as opposed to redistributing existing surface nₛ to the bulk n_{b}. Indeed, in very thin films where the bulk conduction is insignificant, the measured n* (Hall μ*) is always dominated by nₛ (μₛ), staying high (low) and nearly intact upon irradiation (FIGS. 4B and 4C). Given that μₛ is insensitive to the irradiation and μₛ<<μ_{b}, n* and μ* were fitted to the experimental Hall-effect data at various irradiation doses, Such a bilayer model is in good agreement with the experimental data for films with various thicknesses, explaining both the monotonically increasing n* and, in particular, non-monotonic variation of μ* upon irradiation (see representative fitting in FIGS. 5A and 5B). The irradiation-induced, drastic net increase in bulk electron density would shift the weight more toward bulk conduction, compared to the case in pristine films where surface conduction weighs more. Therefore, although μ_{b} slightly decreases upon irradiation, the measured μ* shows an increase at intermediate irradiation doses, because after irradiation the higher-mobility bulk conduction plays a much more significant role than the surface conduction.

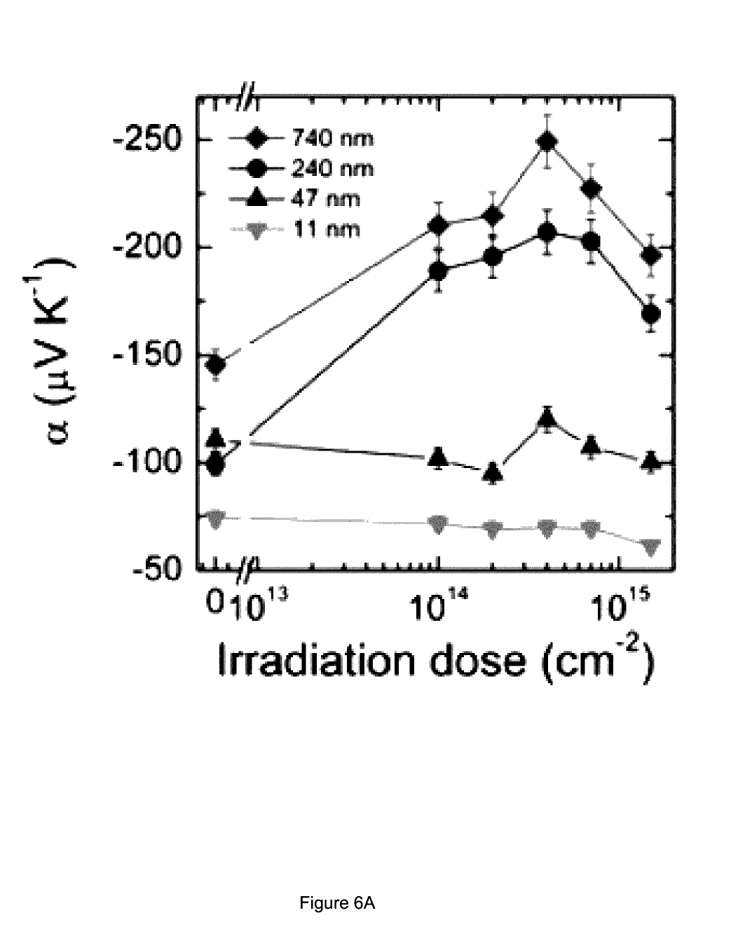

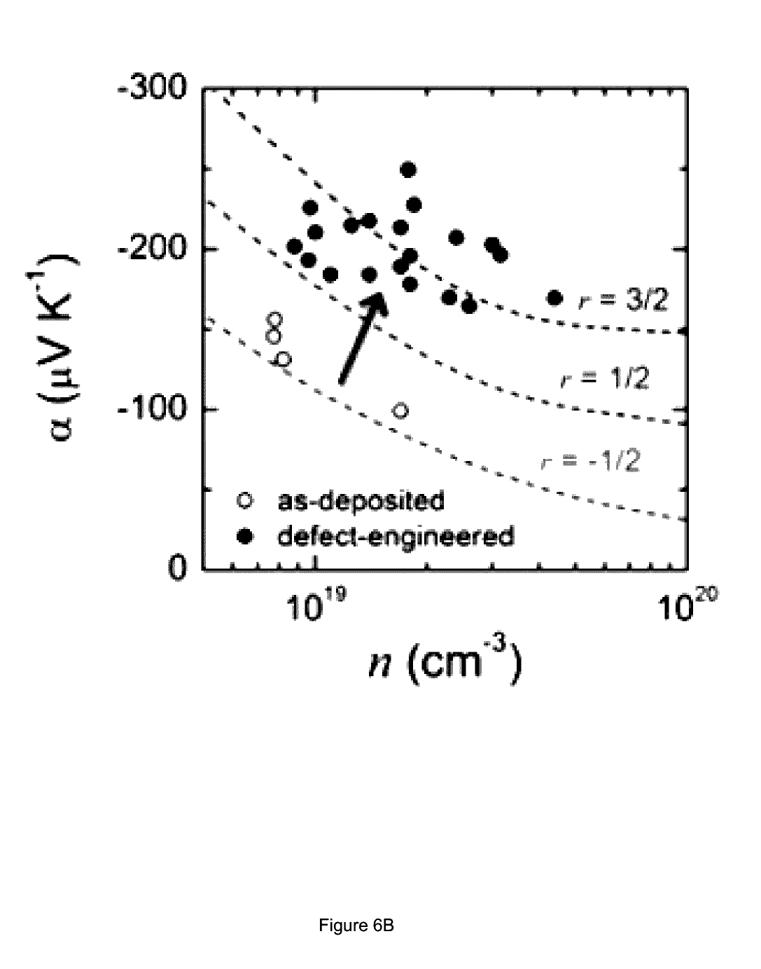

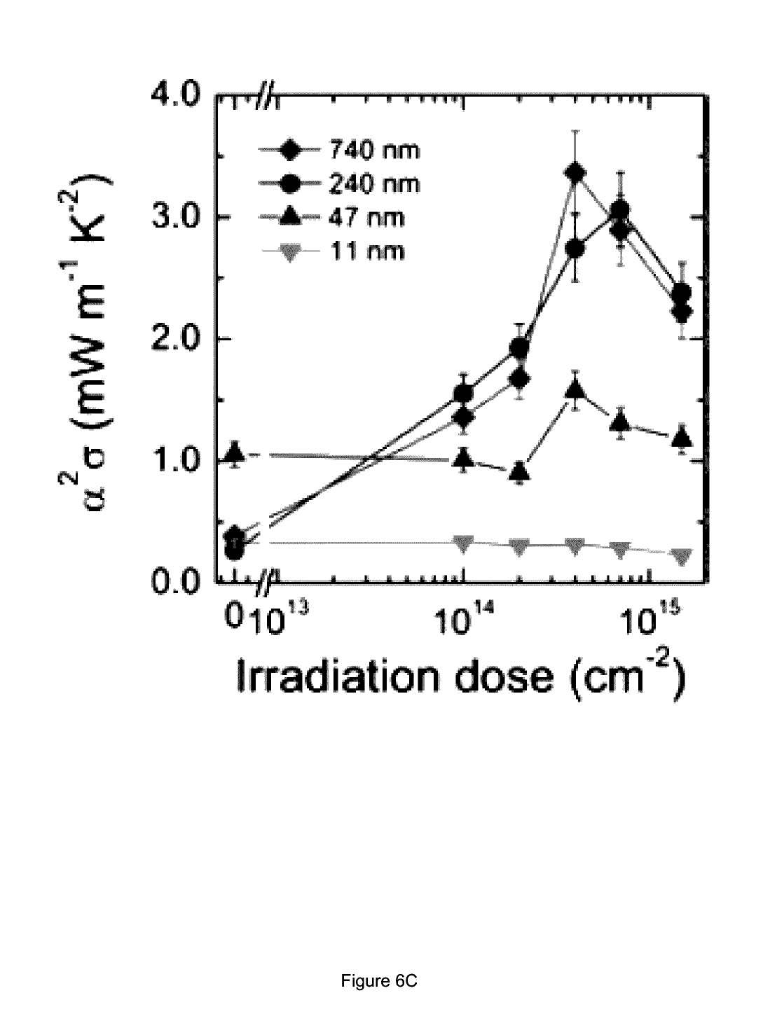

FIGS. 6A-6C show the enhancement of the Seebeck coefficient and power factor by the NDs. FIG. 6A shows the variation of α upon irradiation. While steadily increasing σ, the NDs at intermediate irradiation doses also improve the thermopower, α, of the Bi₂Te₃ films with large thicknesses. This simultaneous enhancement of α and σ is unusual, since in most cases α decreases and σ increases with increasing n. Normally, as n increases, the Fermi level ε_{F} moves deeper into the band where the density of states is flatter, hence reducing the entropy carried by charges around ε_{F}. The simultaneous enhancement of α and σ is observed only in relatively thicker films (>47 nm), which suggests that the measured thermopower is dominated by the bulk contribution that can be tailored by the NDs.

In the relaxation time model, the thermopower in the degenerate doping limit is given by:

$$\vert α \vert \approx \frac{{k}_{B}}{e} \cdot \frac{{π}^{2}}{3} \cdot \frac{{k}_{B} T}{{ɛ}_{F}} \cdot ( \frac{3}{2} + r ) \qquad ( 3 )$$

where r is the index of the electron relaxation time related to kinetic energy, τ(ε)∝ε, and ε_{F} is measured from the conduction band edge. Equation (3) not only predicts the ordinary decrease in α as n increases (through ε_{F}), but also an increase in a when r increases. The former leads to the conventional wisdom of the inverse coupling between α and σ, while the latter allows it to be broken, as in this case. It is known that r varies from −½ for acoustic phonon scattering to 3/2 for ionized impurity scattering.

FIG. 6B shows α enhancement of irradiated Bi₂Te₃ films in the thick film regime (Pisarenko plot). The dotted lines show the results of calculated Seebeck coefficient with different scattering time index r ranging from phonon-scattering (−½) to ionized impurity-scattering ( 3/2). Here the rigorous Fermi-Dirac carrier statistics are used such that the calculation is valid across all concentrations ranging from non-degenerate to degenerate. The arrow indicates simultaneous increase of α and carrier concentration (n) of the films.

As shown in FIG. 6B, in pristine films, the measured α as a function of n follows the trend with calculation using r=−½, indicating that electrons are mostly scattered by phonons in these films. This is consistent with theoretical prediction that electrical transport in Bi₂Te₃ at similar carrier concentrations (˜1×10¹⁹ cm⁻³) is limited by phonon scattering, and is indeed reasonable considering its very large dielectric constant (εₛ=290). However, the high density and multiple charge states of NDs introduced by irradiation as ionized impurities cause a transition of the scattering mechanism from phonon-dominated (r=−½) toward more impurity-dominated (r= 3/2); as a result, the thermopower is drastically enhanced, as indicated by the arrows in FIG. 6B. For the irradiated films, a starts to follow the calculated trend with r= 3/2. This transition is also confirmed by the fact that the mobility μ of the pristine film becomes much higher when measured at low temperatures, while μ is less temperature-sensitive for irradiated films.

FIG. 6C shows the thermoelectric power factor enhancement in the ND-engineered Bi₂Te₃ films. The ND-enabled decoupling of α and σ naturally leads to a significant increase in the thermoelectric power factor, α²σ. It reaches a peak value of 3.4±0.3 mW m⁻¹ K⁻² for the 740 nm film at an irradiation dose of 4×10¹⁴ cm⁻², representing an eight-fold enhancement from its pristine value. This peak power factor is a factor of 1.5 to 3 higher compared to recently reported values in binary Bi₂Te₃.

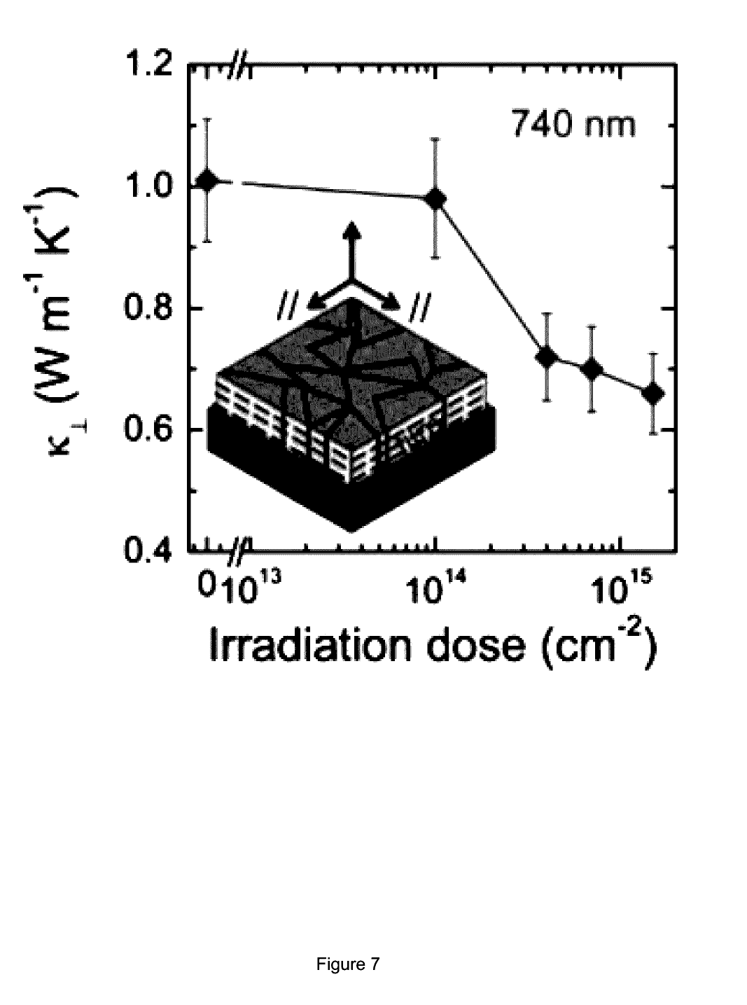

In addition, the effect of the NDs on the cross-plane (c-axis) thermal conductivity (κ_{⊥}), particularly in the thick Bi₂Te₃ films, was investigated using the differential 3ω technique. It was found that κ_{⊥} decreases by up to 35% upon the irradiation, as shown in FIG. 7. It is noteworthy that the reduction in κ_{⊥} is substantially stronger than would be expected if the NDs were replaced by conventional donor ions at the same concentrations (˜3×10¹⁹ cm⁻³, or ˜0.1% of the atomic sites). This is because a point defect's ability to scatter acoustic phonons goes as the are of the defect's relative deviation in mass, radius, and/or bonding strength. These relative deviations are much stronger for the irradiation-introduced NDs (vacancies, anti-sites, and missing bonds) as compared to simple substitutional dopants. As the measured κ is cross-plane (⊥), while the measured α and σ are in-plane (//), a rigorous evaluation of ZT is not straightforward due to the anisotropic transport. However, given the eight-fold enhancement in α²σ, it is safe to conclude that ZT_{//} is expected to be enhanced accordingly because κ is expected to only decrease upon the irradiation.

To summarize, irradiation-induced NDs enhance thermoelectric properties in Bi₂Te₃ by decoupling the three key thermoelectric parameters and simultaneously modifying all of them toward the desired direction. This is enabled by the multiple functionality of the NDs acting beneficially as electron donors, energy-dependent charge scattering centers, and phonon Mockers. The results suggest that a significant improvement of the thermoelectric performance can be achieved through a judicious control of the ND species and their density by post-growth processing. As the NDs are expected to be generated and behave in the similar way in a wide range of narrow-bandgap semiconductors (e.g., observed in InN and InAs), it is possible to extend this method to improve the figure-of-merit of other materials in conjunction with other widely utilized techniques such as alloying and nano- and hetero-structuring.

Potential applications of the methods and materials related to thin film thermoelectric materials disclosed herein include on-chip cooling. Also, the methods and materials can be used to complement existing nanotechnology to scale up in bulk thermoelectrics. For instance, nano-objects (such as Bi₂Te₃ nanowires, particles, or nanoplates, for example) could be irradiated and then pressed into bulk or assembled into bulk using a polymer matrix.

### CONCLUSION

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

What is claimed is:

1. A method comprising:
(a) providing a thermoelectric material; and
(b) irradiating the thermoelectric material with charged particles to generated native defects in the thermoelectric material, the charged particles having energies of about 100 keV or greater.

2. The method of claim 1, wherein the charged particles are selected from a group consisting of protons, alpha particles, nitrogen ions, and neon ions.

3. The method of claim 1, wherein the charged particles comprise protons, and wherein the charged particles have energies of about 1 MeV to 100 MeV.

4. The method of claim 1, wherein the charged particles comprise alpha particles, and wherein the charged particles have energies of about 1 MeV to 100 MeV.

5. The method of claim 1, wherein the charged particles comprise nitrogen ions, and wherein the charged particles have energies of about 100 keV to 100 MeV.

6. The method of claim 1, wherein the charged particles comprise neon ions, and wherein the charged particles have energies of about 100 keV to 2 MeV.

7. The method of claim 1, wherein the charged particles are provided by a cyclotron, a high voltage accelerator, or a focused ion beam apparatus.

8. The method of claim 1, wherein the thermoelectric material in a vacuum environ me during operation (b).

9. The method of claim 1, wherein the thermoelectric material comprises a material selected from a group consisting of an antimony telluride-based material, an antimony selenide-based material, a bismuth telluride-based material, a bismuth selenide-based material, a lead telluride-based material, a lead selenide-based material, a tin telluride-based material, and a tin selenide-based material.

10. The method of claim 1, wherein the thermoelectric material is about 0.5 microns to 300 microns thick.

11. The method of claim 1, wherein operation (b) increases a thermopower and an electrical conductivity of the thermoelectric material.

12. The method of claim 1, wherein operation (b) increases a Seebeck coefficient of the thermoelectric material to greater than about 200 microvolts per Kelvin.

13. The method of claim 1, wherein the thermoelectric material comprises Bi₂Te₃, and wherein the charged particles comprise alpha particles.

14. The method of claim 1, further comprising:
(c) after operation. (b), thermally annealing the thermoelectric material.

15. The method of claim 14, wherein the thermoelectric material is thermally annealed at about 100° C. to 600° C. for a time period of about 30 seconds to 30 minutes.

16. The method of claim 14, wherein the thermoelectric material is thermally annealed in a vacuum environment or in a nitrogen atmosphere.

17. A method of improving the thermoelectric properties of a material, the method comprising:
providing a thermoelectric material; and
irradiating the thermoelectric material with charged particles to generated native defects in the thermoelectric material, the charged particles having energies of about 100 keV or greater, the thermoelectric material having a Seebeck coefficient of greater than about 200 microvolts per Kelvin after the irradiation.

18. A composition comprising:
a thermoelectric material, the thermoelectric material having a native defect density on the same order as a free carrier concentration in the thermoelectric material.

19. The composition of claim 18, wherein the thermoelectric material comprises a material selected from a group consisting of an antimony telluride-based material, an antimony selenide-based material, a bismuth telluride-based material, a bismuth selenide-based material, a lead telluride-based material, a lead selenide-based material, a tin telluride-based material, and a tin selenide-based material.

20. The composition of claim 18, wherein the thermoelectric material has a Seebeck coefficient of greater than about 200 microvolts per Kelvin.
